(19) United States
(12) Patent Application Publication
(10) Pub. No.: US 2024/0389477 A1
(43) Pub. Date: Nov. 21, 2024

(54) SUPERCONDUCTOR-SEMICONDUCTOR CIRCUIT FOR READOUT OF SUPERCONDUCTOR CURRENT-STORAGE ELEMENTS

(71) Applicant: Government of the United States of America, as represented by the Secretary of Commerce, Gaithersburg, MD (US)

(72) Inventor: Jeffrey Michael Shainline, Boulder, CO (US)

(21) Appl. No.: 18/667,298

(22) Filed: May 17, 2024

Related U.S. Application Data
(60) Provisional application No. 63/467,551, filed on May 18, 2023.

(51) Int. Cl. H10N 60/35; H03K 3/38; H10N 60/10; H10N 60/12; H10N 69/00

(52) U.S. Cl. CPC H10N 60/35; H03K 3/38; H10N 60/12; H10N 60/128; H10N 69/00

(57) ABSTRACT

Embodiments of the present invention relate to a superconducting signal storage circuit for integrating and/or storing signals locally as current that can be stored indefinitely in a superconducting wire or inductor. Low-noise readout is accomplished through a transistor circuit that transduces the integrated current signal to a charge on a capacitor. A nanocryotron element generates a voltage across its channel when a sum of the integrated current and a ramp current applied by the transistor circuit reaches a threshold value. This generated voltage switches the gates of an inverter, which terminates the current flow to the capacitor. The accumulated charge on the capacitor is proportional to the current in the storage element that was present when the nanocryotron sensing gate switched from the superconducting state to the resistive state. The charge on capacitor is read by opening a transistor to provide an access line to the capacitor.

### CROSS-REFERENCE TO RELATED APPLICATION

This application claims the benefit of priority from U.S. Provisional Patent Application Ser. No. 63/467,551, filed on May 18, 2023, the disclosure of which is incorporated herein by reference in its entirety.

### STATEMENT REGARDING FEDERAL RIGHTS

The invention described herein was made with United States Government support from the National Institute of Standards and Technology (NIST), an agency of the United States Department of Commerce. The United States Government has certain rights in the invention.

### FIELD OF THE INVENTION

The present invention relates generally to superconducting electronics, and more particularly, to readout of supercurrent stored in superconducting inductive wire.

### BACKGROUND OF THE INVENTION

Superconducting electronics are being incorporated in many systems, ranging from advanced sensors to high-performance computers. In many of these systems, signals are represented by supercurrents in superconducting wires and inductors. In order for these circuits to interface with conventional semiconductor electronics, these currents must be converted into voltages that can be detected by semiconductor circuits. In conventional semiconductor sensor applications, the state of a sensor element is determined by the amount of charge on a capacitor. One means to interface superconductors to semiconductors is to convert current in a superconducting wire to charge on a capacitor so that a conventional complementary metal oxide semiconductor (CMOS) circuit can be used to read that charge.

Accordingly, in order to facilitate the integration of superconducting device and/or sensor functionality with the utility of mature semiconductor electronics, there is a need for an interface that can convert current in a superconducting wire to charge on a capacitor rapidly and with low energy so that the signals present in superconducting systems can be converted to voltage detected by conventional CMOS electronics.

### SUMMARY OF THE INVENTION

Embodiments of the present invention provide a superconducting-semiconductor circuit for transducing current in a superconducting wire, or inductor, to charge on a capacitor for readout of superconductor current-storage elements. Low-noise readout is accomplished through a transistor circuit that transduces the integrated current signal to a charge on a capacitor. A transistor provides a ramp for adding current, or current pulses, to the integrated current while another transistor delivers a fixed current to an integration capacitor when the first transistor begins its ramp current. A nanocryotron gate element detects whether the sum of integrated current and the current applied by the first transistor has reached a threshold value and generates a voltage across nanocryotron switching element channel at the threshold value. The voltage generated across nanocryotron switching clement channel switches the gates of an inverter, which terminates the current flow to the capacitor. The charge accumulated on capacitor when transistor terminates the current flow to capacitor is inversely proportional to the integrated current that was present in the superconducting wire or inductor when the measurement procedure began. When used in conjunction with a single-photon detector as an input, this charge serves as a proxy for the number of photons that were detected during integration, with the number of electrons having a direct correspondence to the number of detected photons. The charge on capacitor is read by opening a fourth transistor, which is positioned to provide an access line to capacitor for reading the accumulated charge on the capacitor as a readout signal. This approach decouples the events that add current to the superconducting wire or inductive storage element from the readout process. Low-noise readout can be accomplished through a measurement duration that is not limited by the temporal extent of the current pulse that drove the integration or storage element in the first place. Integration of Josephson junctions with a nanocryotron interface to metal oxide semiconductor field effect transistors (MOSFETs) enables a low-noise, scalable readout framework for superconducting current-storage elements, only sends the required information to room temperature, and transduces low-voltage superconductor signals to semiconductor-level voltages to be processed by conventional silicon electronics.

Embodiments of the present invention relate to a superconducting signal storage circuit, including a transduction circuit for generating an integrated first current pulse in response to a plurality of electrical signals received from an input circuit; a first transistor for applying a second current to interrogate the first current generated by the transduction circuit, wherein the second current is added to the first current to generate a third current; a second transistor for generating a fourth current, wherein the fourth current is substantially equal to the first current from the transduction circuit; a cryotron switching clement comprising a cryotron gate and a cryotron channel, wherein the cryotron switching element is positioned to receive the third current through the cryotron gate and a fifth current through the cryotron channel, wherein the cryotron switching clement switches the cryotron gate and the cryotron channel from a superconducting state to a normal metal state at a threshold value of the third current, wherein the fifth current through the switched cryotron channel in the normal metal state induces a first voltage; a capacitor positioned to receive the fourth current from the second transistor and accumulate a charge equivalent to the received fourth current; a semiconductor element comprising a third transistor and a fourth transistor for inducing a second voltage, wherein the first voltage induced by the switched cryotron channel switches off the third and the fourth transistors, wherein the switched off the third and the fourth transistors induce the second voltage, wherein the induced second voltage switches off the fourth current to the capacitor; a fifth transistor coupled to the capacitor to provide an access line for reading the accumulated charge on the capacitor, wherein a third voltage opens the fifth transistor to transfer the accumulated charge on the capacitor to the access line as a readout signal; and a column bus coupled to the fifth transistor to receive the readout signal. More particularly, each of the first, the second, the third, the fourth and the fifth transistors is a metal oxide semiconductor field effect transistor.

In some embodiments of the present invention, the superconducting signal storage circuit further includes a multiplexing element for multiplexing the readout signal received by the column bus; and an analog-to-digital converter for converting the multiplexed readout signal to a digital signal.

In one embodiment of the present invention, the cryotron switching element is a heater cryotron (hTron) switching element.

In another embodiment of the present invention, the cryotron switching element is a nano cryotron (nTron) switching element.

In yet another embodiment of the present invention, the cryotron switching element is a current-crowding cryotron (yTron) switching element.

Another embodiment of the present invention relates to a superconducting signal storage circuit including a direct current single-flux-quantum converter for converting each of a plurality of electrical signals received from an input circuit to a single-flux-quantum; a detector integration loop for inducing an integrated first current proportional to the single-flux-quantum converted from the each of the plurality of the electrical signals received from the input circuit; a Josephson transmission line comprising a plurality of Josephson junctions for propagating the single-flux-quantum from the direct current single-flux-quantum converter to the detector integration loop; and a readout element for reading the induced integrated first current from the detector integration loop, wherein the readout element comprises: a first transistor for applying a second current to the integrated first current from the detector integration loop circuit to generate a third current; a second transistor for generating a fourth current, wherein the fourth current is substantially equal to the first current from the detector integration loop circuit; a cryotron switching element comprising a cryotron gate and a cryotron channel, wherein the cryotron switching element is positioned to receive the third current through the cryotron gate and a fifth current through the cryotron channel, wherein the cryotron switching element switches the cryotron gate and the cryotron channel from a superconducting state to a normal metal state at a threshold value of the third current, wherein the fifth current through the switched cryotron channel in the normal metal state induces a first voltage; a capacitor positioned to receive the fourth current from the second transistor and accumulate a charge equivalent to the received fourth current; a semiconductor clement comprising a third transistor and a fourth transistor for inducing a second voltage, wherein the first voltage induced by the cryotron channel switches off the third and the fourth transistors, wherein the switched off the third and the fourth transistors induce the second voltage, wherein the induced second voltage switches off the fourth current to the capacitor; a fifth transistor coupled to the capacitor to provide an access line for reading the accumulated charge on the capacitor, wherein a third voltage opens the fifth transistor to transfer the accumulated charge on the capacitor to the access line as a readout signal; and a column bus coupled to the fifth transistor to receive the readout signal. More particularly, each of the first, the second, the third, the fourth and the fifth transistors is a metal oxide semiconductor field effect transistor. In one embodiment of the present invention, the cryotron switching clement is a heater cryotron (hTron) switching element. In another embodiment of the present invention, the cryotron switching element is a nano cryotron (nTron) switching element. In yet another embodiment of the present invention, the cryotron switching element is a current-crowding cryotron (yTron) switching element.

Embodiments of the present invention also relate to a superconducting signal storage circuit including a first transistor for applying a first current to an integrated second current received from a transduction circuit, wherein the applying the first current to the integrated second current comprises adding the first current to the integrated second current to generate a third current; a second transistor for generating a fourth current, wherein the fourth current is substantially equal to the integrated second current; a cryotron switching element positioned to receive the third current through a cryotron gate and a fifth current through a cryotron channel, wherein the cryotron switching element switches the cryotron gate and the cryotron channel from a superconducting state to a normal metal state at a threshold value of the third current, wherein the fifth current through the switched cryotron channel in the normal metal state induces a first voltage; a capacitor positioned to receive the fourth current from the second transistor and accumulate a charge equivalent to the received fourth current; a semiconductor element comprising a third transistor and a fourth transistor for inducing a second voltage, wherein the first voltage induced by the switched cryotron channel switches off the third and the fourth transistors, wherein the switched off the third and the fourth transistors induce the second voltage, wherein the induced second voltage switches off the fourth current to the capacitor; a fifth transistor coupled to the capacitor to provide an access line for reading the accumulated charge on the capacitor, wherein a third voltage opens the fifth transistor to transfer the accumulated charge on the capacitor to the access line as a readout signal; and a column bus coupled to the fifth transistor to receive the readout signal. In one embodiment of the present invention, the cryotron switching clement is a heater cryotron (hTron) switching element. In another embodiment of the present invention, the cryotron switching element is a nano cryotron (nTron) switching element. In yet another embodiment of the present invention, the cryotron switching element is a current-crowding cryotron (yTron) switching element.

In some embodiments of the present invention, the transduction circuit further includes a direct current single-flux-quantum converter for converting each of a plurality of electrical signals received from an input circuit to a single-flux-quantum; a detector integration loop for inducing the integrated first current proportional to the single-flux-quantum converted for each of the plurality of the electrical signals received from the input circuit; and a Josephson transmission line comprising a plurality of Josephson junctions for propagating the single-flux-quantum from the direct current single-flux-quantum converter to the detector integration loop.

In some embodiments of the present invention, the superconducting signal storage circuit further includes a multiplexing element for multiplexing the readout signal received by the column bus; and an analog-to-digital converter for converting the multiplexed readout signal to a digital signal.

### BRIEF DESCRIPTION OF DRAWINGS

FIG. 1 illustrates a superconducting signal storage elements array in accordance with embodiments of the present invention.

FIG. 2 illustrates a superconducting signal storage circuit in accordance with an embodiment of the present invention.

FIG. 3 illustrates an exemplary implementation of a SPD pixel in accordance with an embodiment of the present invention.

FIG. 4 illustrates an exemplary implementation of SPD-SFQ transduction circuit in accordance with an embodiment of the present invention.

FIG. 5 illustrates results from simulations to determine bias ranges for the exemplary SPD-SFQ transduction circuit shown in FIG. 4.

FIG. 6 illustrates results from operation of an exemplary SPD-SFQ transduction circuit in accordance with embodiments of the present invention.

FIG. 7 illustrates regions of an exemplary SPD-SFQ operation when β_{sq} is set to a predetermined value.

FIG. 8 illustrates time traces for β_{di}=1.3 showing saturation above I_{c} in an integration loop of exemplary SPD-SFQ transduction circuit in accordance with embodiments of the present invention.

FIG. 9 illustrates an exemplary readout architecture for an SPD pixel array in accordance with an embodiment of the present invention.

FIG. 10 illustrates a microscopic image of an exemplary SPD pixel in accordance with an embodiment of the present invention.

FIG. 11A and FIG. 11B illustrate plots of the voltage across the SQUID as a function of time when optical pulses are directed at a fixed rate to the exemplary SPD pixel shown in FIG. 10.

FIG. 11C and FIG. 11D illustrate plots of the voltage across the SQUID as a function of time when optical pulses are directed at a fixed rate to the exemplary SPD pixel shown in FIG. 10.

FIG. 12A and FIG. 12B illustrate plots of the voltage across the SQUID as a function of time for varying current pulse widths.

FIG. 13A and FIG. 13B illustrate plots showing the voltage on the readout SQUID as a function of the frequency of input photonic pulses.

FIG. 14A and FIG. 14B illustrate comparisons of readout performance from standalone and integrated SPDs.

### DETAILED DESCRIPTION

While the making and using of various embodiments of the present invention are discussed in detail below, it should be appreciated that the present invention provides many applicable inventive concepts which can be embodied in a wide variety of specific contexts. The specific embodiments discussed herein are merely illustrative of specific ways to make and use the invention, and do not delimit the scope of the present invention. Reference will now be made to the drawings wherein like numerals refer to like elements throughout.

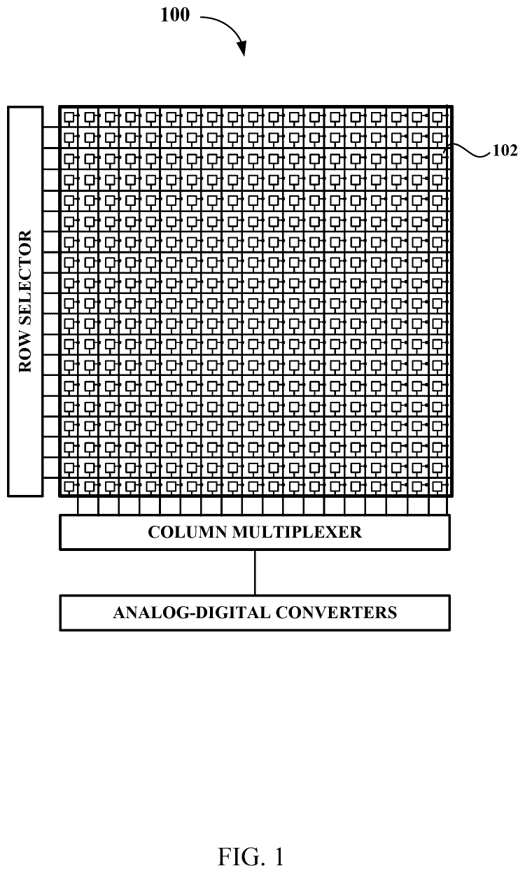

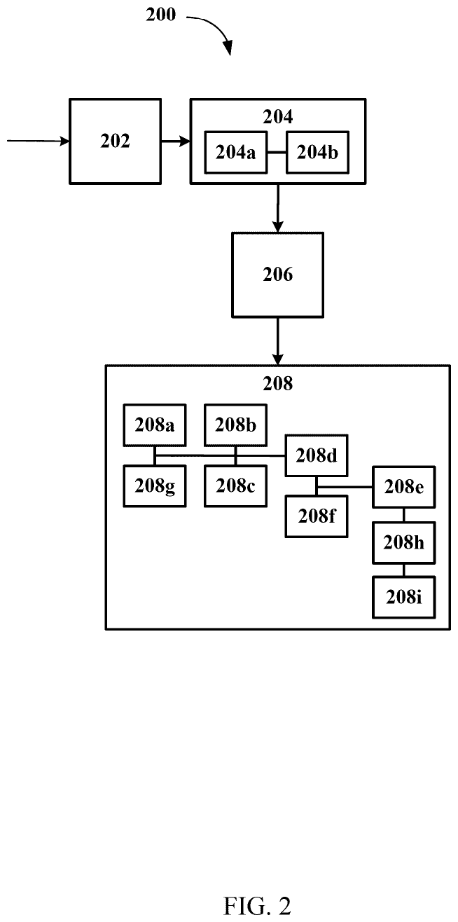

Referring now to the drawings, and more particularly, to FIG. 1, there is shown a superconducting signal storage array, generally designated 100 and schematically showing an embodiment of the present invention. Superconducting signal storage elements array 100 is formed by individual superconducting signal storage circuits 102 arranged in rows and columns to form an array, one of which is shown in FIG. 2. In one embodiment of the present invention, the array is arranged in rows and columns of 3×3 million superconducting signal storage circuits. In some embodiments of the present invention, superconducting signal storage elements array 100 is formed by single photon detector (SPD) pixels arranged in rows and columns to form an array.

Referring to FIG. 2, each superconducting signal storage circuit 200 receives current or flux from an input circuit or element, integrates the current received from the input circuit, transduces each current pulse or flux received from the input circuit or element to an electrical signal, which may be in the form of a single-flux-quantum (SFQ), stores the current or SFQ locally, and amplifies charge readout for data extraction. Superconducting signal storage circuit 200 includes a direct current supercondcuting quantum interference device (DC-SQUID), which may be configured as a SQF converter 202 for converting the current or flux received from the input circuit or clement to SFQ, a Josephson transmission line 204 for propagating the SFQ, a detector integration (DI) loop 206 for inducing an integrated current proportional to the SFQ added for each current pulse or flux received from the input circuit or element, and a readout element 208 for reading the integrated current in DI loop 206 and multiplexing data into single transmission lines for transfer to an analog to digital converter (ADC).

DC SQUID or SQF converter 202 converts the electrical signals received from the input circuit or element to SFQ. In one embodiment of the present invention, the input circuit includes a single-photon detector (SPD) that detects a photon. SPD breaks superconductivity and causes a resistive hot spot when it absorbs a photon, and diverts a bias current from SPD as a SPD current through a transformer. The transformer is inductively-coupled to DC SQUID or SQF converter 202 and drives a flux into DC SQUID or SQF converter 202. The flux is a product of the SPD current and the mutual inductance of the transformer. DC SQUID or SQF converter 202 transduces each detected photon into an individual fluxon. In some embodiments, a fluxon is a quantum of magnetic flux denoted by and equal to ϕ₀=h/2e˜2 mV·ps. Each fluxon generated by DC SQUID or SQF converter 202 propagates through Josephson transmission lines 204 to DI loop 206. In some embodiments, Josephson transmission line 204 includes two Josephson junctions 204a and 204b positioned between DC SQUID or SQF converter 202 and DI loop 206.

DI loop 206 includes an inductive loop that stores each fluxon propagated through Josephson transmission line 204 as current and the repeated electrical signals received are summed. In embodiments of the present invention wherein the input circuit includes a SPD, the amount of current added to DI loop 206 per photon detection is ϕ₀/L, where L is the loop inductance. After an integration period, DI loop 206 contains a current proportional to the number of electrical signals received. In one embodiment of the present invention, the current stored in DI loop 206 immediately preceding a read event is proportional to the total number of electrical signals that have been received in that integrate-read cycle. In such embodiments, superconducting signal storage circuit 200 is an energy meter. In another embodiment of the present invention, DI loop 206 includes a finite resistance, and the integrated signal leaks at a rate provided by the loop time constant τ=L/r. The signal stored in superconducting signal storage circuit 200 is proportional to the rate of electrical signals received in the preceding time interval of order τ. In such embodiments, no external signal is required to reset the loop. This is a leaky integrator wherein the signal is proportional to the recent rate of electrical signals received. In such embodiments, superconducting signal storage circuit 200 is a power meter. Accordingly, superconducting signal storage circuit 200 can be used in energy integration mode or in power integration mode with the inclusion of a resistive element in DI loop 206 to establish a leak rate.

Readout element 208 includes a transistor 208a that provides a ramp for adding current, or current pulse, to DI loop 206 and a transistor 208d that begins delivering a fixed current to a capacitor 208f when transistor 208a begins its ramp for adding current. Readout element 208 also includes a cryotron (Tron) switching element 208g having a cryotron gate clement for detecting whether the sum of integrated current in DI loop 206 and current applied by transistor 208a has reached a threshold value. Cryotron (Tron) switching element 208g further includes a cryotron channel capable of switching between a superconducting state and a resistive or normal state. Cryotron (Tron) switching clement 208g switches the cryotron gate and the cryotron channel from a superconducting state to a normal metal state when the sum of integrated current in DI loop 206 and current applied by transistor 208a reaches a threshold value. A current through the switched cryotron (Tron) switching element 208g channel in the normal metal state induces a voltage. In one embodiment of the present invention, cryotron gate clement 208g is heater cryotron (hTron) switching element. In a second embodiment of the present invention, cryotron gate element 208g is a nano cryotron (nTron) switching clement. In another embodiment of the present invention, cryotron gate clement 208g is a current-crowding crytron (yTron) switching clement. Readout clement 208 further includes an inverter formed by transistors 208b and 208c (also referred to as two-transistor inverter).

In embodiments wherein cryotron gate element 208g is a hTron switching element, when the sum of integrated currents in DI loop 206 and current applied by transistor 208a reaches cryotron gate clement 208g threshold value, cryotron switching clement 208g switches the cryotron gate and the cryotron channel to a high impedance state and a current through the switched cryotron switching clement 208g channel in the high impedance state generates a voltage across cryotron switching clement 208g channel. The voltage generated across cryotron switching clement 208g channel switches the gates of transistors 208b and 208c. Further, cryotron switching clement 208g switches a superconducting clement from a superconducting state to normal state and purges the current in DI loop 206. Transistor 208d terminates the current flow to capacitor 208f when the gates of transistors 208b and 208c are switched. The charge accumulated on capacitor 208f when transistor 208d terminates the current flow to capacitor 208f is inversely proportional to the current that was present in DI loop 206. This charge will now serve as a proxy for the number of electrical signals that were received during integration, with the number of electrons having a direct correspondence to the number of electrical signals received. With the desired information represented as charge on a capacitor, the charge on capacitor 208f is read by opening transistor 208e with a read voltage. Transistor 208e is positioned in readout element 208 to provide an access line to capacitor 208f for reading the accumulated charge on capacitor 208f as a readout signal. In embodiments wherein a plurality of superconducting signal storage circuit 200 is arranged to form an array of superconducting signal storage circuit using row-column architecture, the charge on capacitor 208f in each superconducting signal storage circuit 200 is read by opening transistor 208e in each superconducting signal storage circuit 200 to couple the charge through the access line to a column read bus 208h as readout signal. In one embodiment of the present invention, each of transistors 208a-e is a field-effect transistor (FET). In an exemplary embodiment of the present invention, each of transistors 208a-e is a metal oxide semiconductor field effect transistor (MOSFET).

In some embodiments of the present invention, readout clement 208 is further configured to include a selection switch to select rows for readout in a sequential manner, readout the charge that is stored in capacitor 208f in each superconducting signal storage circuit 200 of superconducting signal storage circuit array 102 one circuit at a time, and transfer the readout signal through a column bus to a multiplexing circuit 208i. Selection of an active row of a superconducting signal storage circuit array can be achieved by using separate selection switches included in readout element 208 of each superconducting signal storage circuit and in series with transistor 208h of that superconducting signal storage circuit. Column buses may be positioned in parallel such that each column bus may be used to provide an electrical connection for every superconducting signal storage circuit in the column of the superconducting signal storage circuit array. Multiplexing circuit 208i is configured to send data readout signal from each column bus to analog to digital converters (ADCs). This aspect of the circuit operation uses methods for reading charge from capacitors in CMOS sensor arrays. The digitized signal from ADC is transferred to a processor for further analysis and processing.

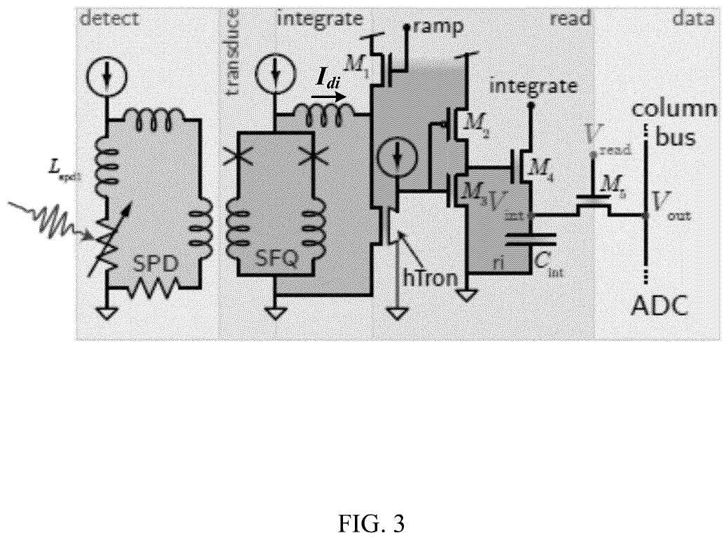

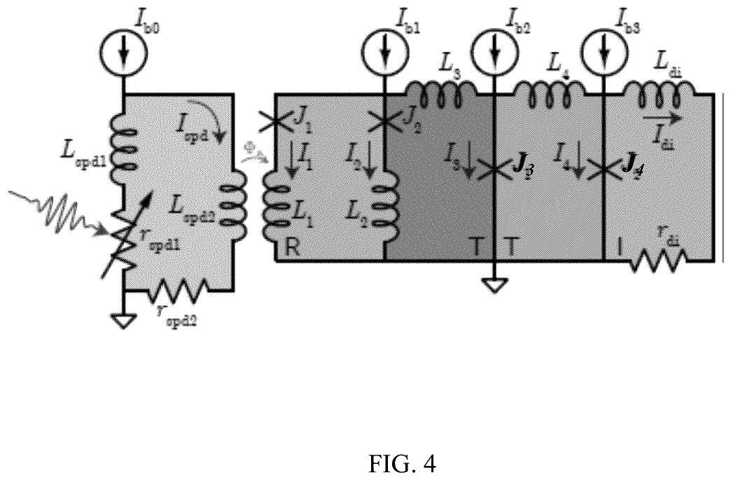

FIG. 3 illustrates an exemplary implementation of superconducting signal storage circuit 200 in accordance with an embodiment of the present invention using a single-photon detector (SPD) pixel. Each time the SPD detects a photon, a bias current (I_{b0}) is diverted as a current pulse (i_{spd}) to a branch of the detection circuit that is coupled to a transformer, as further shown in FIG. 4. The transformer drives a flux into a SFQ converter such that SFQ converter transduces each detected photon into an individual fluxon, which is added to a detector integration (DI) loop with each photon detection event.

FIG. 4 illustrates an exemplary implementation of SPD-SFQ transduction circuit of single-photon detector pixel 200 in accordance with an embodiment of the present invention. The flux added to the SFQ converter switches a Josephson juntion (J₂) to generate one or more fluxons. These fluxons are propagated through two transmission loops (T) including a Josephson transmission line and added to the integration loop (I), as shown in FIG. 4. The exemplary transduction circuit, as shown in FIG. 4, ensures that the SFQ converter generates a SFQ with each SPD click rather than a train of fluxons. This is accomplished through the inductors L₁ and L₂, and the bias conditions. The inductors L₃ and L₄ are chosen based on typical Josephson junction-Transmission loops-Inductance (JTL) design considerations to achieve β_{L}=2πLI_{c}/ϕ₀=2π×5. The transduction circuit shown in FIG. 4 can be analyzed using the following set of equations:

$$\frac{d {i}_{d i}}{dt} = \frac{1}{{β}_{d i}} ( \frac{d {δ}_{4}}{dt} - {α}_{d i} {i}_{d i} ) \qquad ( 1 )$$

$$\frac{{d}^{2} {δ}_{j}}{{dt}^{2}} = \frac{1}{{β}_{c}} [ {i}_{j} - sin ( {δ}_{j} ) - \frac{d {δ}_{j}}{dt} ] \qquad ( 2 )$$

$$\frac{d {i}_{s p d}}{dt} = \frac{1}{{β}_{s p d}} \{ {α}_{s p d} ( t ) {i}_{b 0} - [ {α}_{s p d 1} ( t ) + {α}_{s p d 2} ] {i}_{s p d} \} \qquad ( 3 )$$

where all currents are expressed in dimensionless units as iⱼ=Iⱼ/I_{c}. In Eq. (1), the dimensionless screening parameter is given by β_{di}=2πL_{di}I_{c}/ϕ₀, δ₄ is the phase of the superconducting wave function across J₄, and α_{di}=r_{di}/r; is the dimensionless resistance scaled by the Josephson Junction shunt resistance r. Eq. (2) relates to a JJ in resistively and capacitively shunted junction (RCSJ) model. The Stewart-McCumber parameter β_{c}=2πI_{c}r²cⱼ/Φ₀ with cⱼ as the junction capacitance. An identical equation is included for each JJ (j=1-4). To convert to first order, an additional equation of the form \dot{δ}=δ_{jb} must also be included in the system for each JJ. Eq. (3) models the SPD response, where α_{spd1}(t)=r_{spd1}(t)/rⱼ is the hotspot resistance following each photon detection event. In one embodiment, the hotspot resistance is about 10 kΩ for 300 ps. α_{spd2}=r_{spd2}/rⱼ is chosen to enable SPD recovery without latching. The remaining currents in the circuit can be obtain from the following expressions:

$${i}_{4} = \frac{1}{{β}_{4}} ( {δ}_{3} - {δ}_{4} ) + {i}_{b 3} - {i}_{d i} \qquad ( 4 )$$

$${i}_{3} = {\overline{β}}^{- 1} [ {β}_{1} ( {δ}_{2} - {δ}_{3} ) + {β}_{2} ( {δ}_{1} - {δ}_{3} - 2 π {ϕ}_{a} ) + {β}_{1} {β}_{2} {i}_{b 1} ] + {i}_{b 2} + {i}_{b 3} - {i}_{4} - {i}_{5} \qquad ( 5 )$$

$${i}_{2} = \frac{1}{{β}_{1} + {β}_{2}} ( {δ}_{1} - {δ}_{2} - 2 π {ϕ}_{a} ) + \frac{1}{{β}_{1} + {β}_{2}} ( {i}_{b 1} + {i}_{b 2} + {i}_{b 3} - {i}_{3} - {i}_{4} - {i}_{5} ) \qquad ( 6 )$$

$${i}_{1} = {i}_{b 1} + {i}_{b 2} + {i}_{b 3} - {i}_{2} - {i}_{3} - {i}_{4} - {i}_{5} \qquad ( 7 )$$

where ϕₐ=Φₐ/Φ₀ is the applied flux due to pulses registered by the SPD: Φₐ=MI_{spd}. The mutual inductance M=k\sqrt{L_{spd}L₁} depends on two inductances L₁ and L_{spd}, but L₁ is not a free parameter. L₁ is selected such that SPD-SFQ transduction can be achieved with broad margins. L_{spd} is selected such that Φₐ˜Φ₀/2 when the SPD detects a photon and I_{spd}˜I_{b0}.

In Eqs. (4)-(7), β̅=β₁β₂+β₁β₃+β₂β₃. The SPD is coupled to the SFQ converter in these equations through the term ϕₐ, the normalized applied flux. This term is given by ϕₐ=Φₐ/Φ₀ where ϕₐ(t)=MI_{spd}(t), and M is selected such that Φₐ=Φ₀/2 at peak SPD response.

The exemplary implementation of SPD-SFQ transduction circuit, as shown in FIG. 4, can operate with a broad margin and ensures large integration loop capacity. In the exemplary implementation of SPD-SFQ transduction circuit, as shown in FIG. 4, it is assumed that all JJs have the same current I_{c}. Inductors L₃ and L₄ are selected such that JTL performance is optimal, and L_{di} is selected such that signal integration is optimal. I_{b1} and I_{b2} are selected such that the SPD-SFQ transduction circuit is insensitive to I_{b1} and I_{b2}. In one embodiment of the present invention, I_{b1} and I_{b2} are equal to about 0.71_{c} at t=0. The Stewart-McCumber parameter β_{c} is set to a predetermined value. In one embodiment, the Stewart-McCumber parameter β_{c} is 0.3.

L₁ and L₂ are selected for a range of I_{b1} values such that the SPD-SFQ transduction circuit operates successfully. The inductors are parameterized with

$${β}_{1} = {β}_{s q} ≡ \frac{2 ( {L}_{1} + {L}_{2} ) {I}_{C}}{{Φ}_{0}} .$$

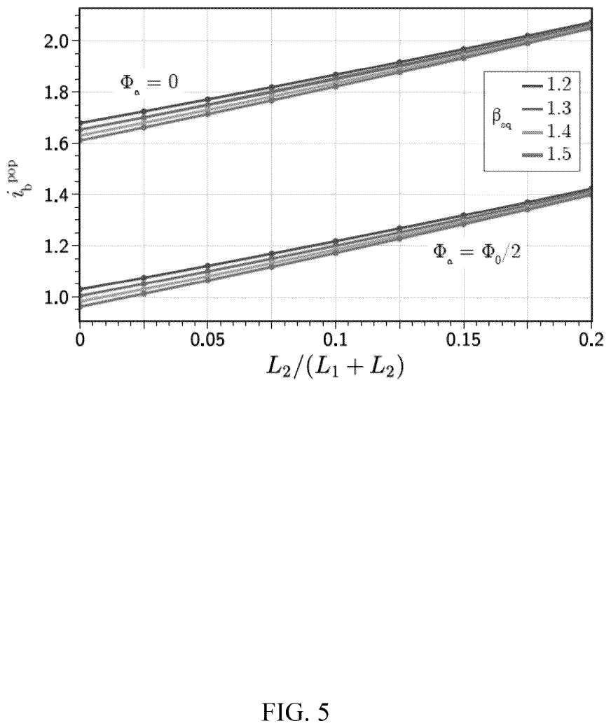

The SPD-SFQ transduction circuit operation can be analyzed as a function of the inductance asymmetry, which can be quantified with L₂/(L₁+L₂). The bias current of interest can be represented in dimensionless units with I_{b1}→i_{b}=I_{b1}/I_{c}. The functional values of i_{b} are determined to ramp i_{b} from zero until J₂ generates the first fluxon. This value of i_{b} is referred to as iₚ^{pop}. FIG. 5 illustrates results from exemplary simulations to determine bias ranges for the exemplary SPD-SFQ transduction circuit, as shown in FIG. 4, for a range of values of the asymmetry L₂/(L₁+L₂), for four values of β_{sq}, and for the applied flux from the SPD (Φₐ) equal to the minimum value of zero and the maximum value of Φ₀/2. In order to operate the two JJ circuits shown in FIG. 4 as a SFQ converter, β_{sq}, L₂/(L₁+L₂) and i_{b} are set to a predetermined value, the applied flux is ramped up in time from ϕₐ=0 to ϕₐ=½, and then ramped down.

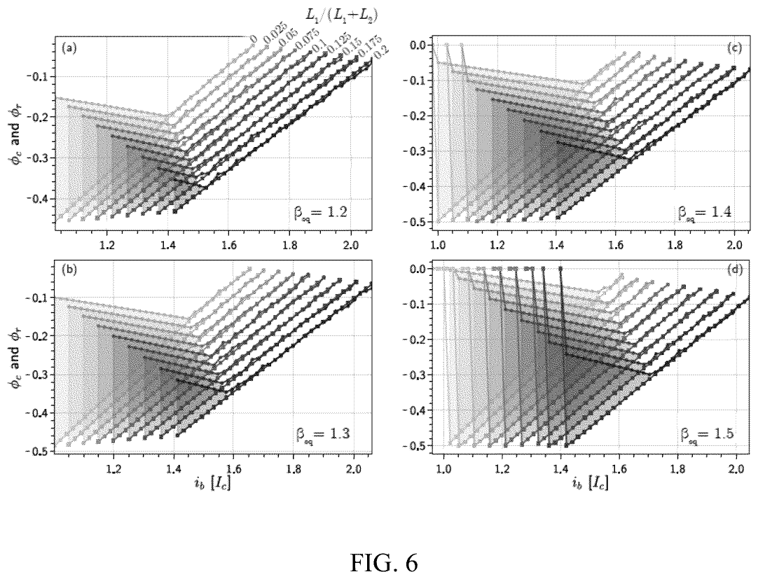

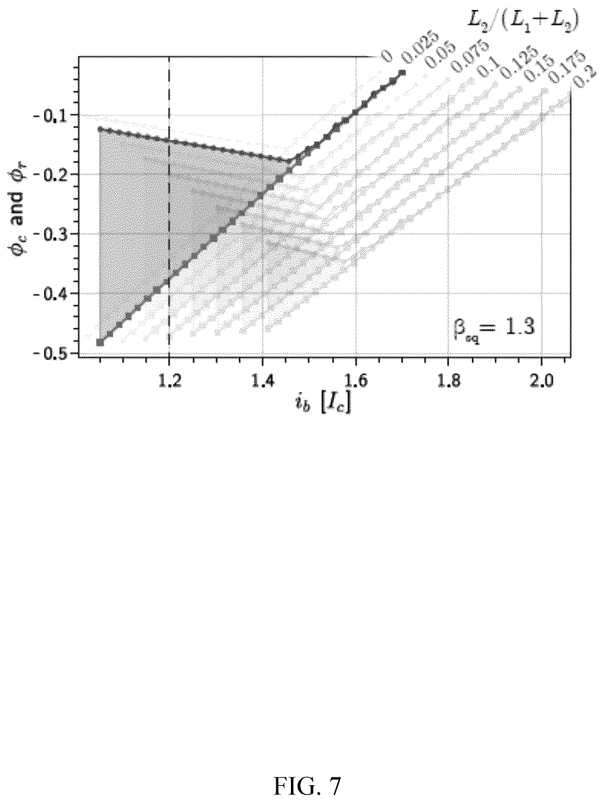

FIG. 6 illustrates exemplary results of an SPD-SFQ operation in accordance with embodiments of the present invention. FIG. 6 illustrates the values of ϕₐ as a function of i_{b} when the applied flux is ramped up in time from ϕₐ=0 to ϕₐ=½ in the two JJ circuits shown in FIG. 4 and the JJ circuit generates the first fluxon, which is referred to as the critical value of applied flux ϕ_{c}. FIG. 6 also illustrates the values of ϕₐ as a function of i_{b} when the applied flux is ramped down in the two JJ circuits shown in FIG. 4 and the JJ circuit generates the last fluxon, which is referred to as the reset value of applied flux ϕᵣ. Each panel in FIG. 6 shows plots for different asymmetry values of L₂/(L₁+L₂) for a specific β_{sq} value. The open regions in the plots in each panel of FIG. 6 indicate instances when one fluxon is generated by crossing the threshold of applied flux at ϕ_{c} and when another fluxon is produced when the applied flux drops below ϕᵣ. These regions indicate SFQ operation. FIG. 7 illustrates exemplary regions of SPD-SFQ operation when β_{sq}=1.3. A preferred bias point when L₂/(L₁+L₂)˜0.025 is represented by a vertical dashed line in FIG. 7.

The DI loop of the exemplary SPD-SFQ transduction circuit of SPD pixel in accordance with an embodiment of the present invention, as shown in FIG. 4, performs integration. One fluxon is added to the loop with each photon detection event, and the amount of current in the DI loop depends on the inductance L_{di} of the loop. Inductance L_{di} determines the loop capacity as well as the spacing between levels. When the element that adds current to the superconducting signal-storage element is a SFQ converter, the spacing between current levels is set by the current associated with each SFQ pulses. This current is Φ₀/L, so this is also the spacing between levels. The loop capacity is defined as the number of SFQ pulses that can be added to the superconducting signal-storage element before additional inputs to the transducer cease to add signal to the storage element. Signal will cease to be added when the current in the storage element reaches a certain level that depends on the bias to the circuit. Defining this current as Iₘₐₓ, the number of SFQ pulses that can be stored is N_{fq}=Iₘₐₓ/(Φ₀/L). The loop will saturate and stop receiving fluxons when the integrated current I_{di} reaches a value that is equal to about the JJ circuit current I_{c}. That is, Iₘₐₓ˜I_{c}. The number of fluxons this corresponds to, and the number of photon detection events, is set by inductance L_{di}. This capacity is typically quantified in terms of the dimensionless parameter β_{L}/2π=LI_{c}/Φ₀, and β₁/2π will quantify the number of fluxons the loop can store. The number of bits of information stored in the DI loop is log₂(β_{L}/2π). A larger B_{L} can store more events, but the levels become more closely spaced and places further demands on the analog-to-digital conversion at the readout stage. In the exemplary embodiment of the present invention, as shown FIG. 4, the DI loop can store form about 10 bits to about 11 bits having from about 1024 levels to about 2048 levels. In some embodiments of the exemplary SPD transduction circuit, as shown in FIG. 4, the DI loop can include a resistor to set a τ_{di}=L_{di}/r_{di} leak rate and function as a power meter to provide a running average of the number of photon detection events in the last τ_{di} seconds. In the absence of a resistor, the DI loop retains signal indefinitely, functions as an energy meter, and only purges the information through a destructive read operation.

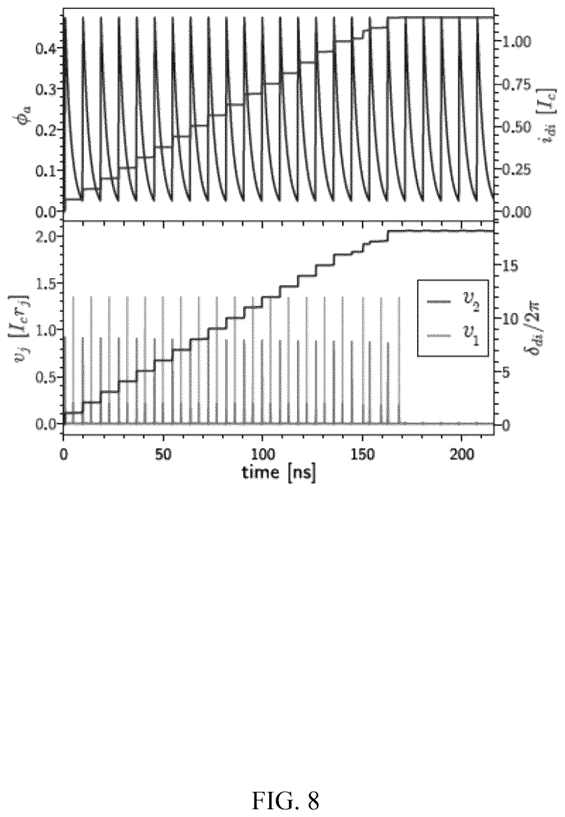

FIG. 8 illustrates exemplary time traces for β_{di}=1.3 showing saturation above I_{c} in a DI loop with β_{di}/2π=16. The top panel of FIG. 8 shows applied flux ϕₐ from a train of simulated SPD pulses on the left y-axis and integrated current I_{c} in the DI loop on the right y-axis. The bottom panel of FIG. 8 shows the voltages vⱼ of the two JJs in the receiving loop on the left y-axis, and reveals that the JJs cease to produce voltage pulses corresponding to fluxons for saturations above I_{c}. The bottom panel of FIG. 8 further shows the phase of the JJ (J₄) in the integration loop on the right y-axis, and that δ_{di}/2π reaches β_{di}/2π=16. In another exemplary embodiment of the present invention, it was observed that the JJ circuit having β_{di}=2¹⁰=1024 saturates with an integrated current exceeding I_{c} and stores over 1024 fluxons.

Referring to FIG. 3, after an integration period, the DI loop includes a current proportional to the number of photons that have been detected. The next block of the exemplary SPD pixel circuit, as shown in FIG. 3, is a read circuit that reads the integrated current induced by the DI loop. In the read circuit, transistor M₁ ramps the current through the gate of the hTron to interrogate the integrated current I_{di}, and transistor M₄ generates an integrate current I_{di} to deliver charge to the capacitor Cᵢₙₜ. This charge is a proxy for the current I_{di}. The total current through the hTron gate is the sum of the ramp current from transistor M₁ and the integrated current I_{di}. The current threshold for the hTron gate is selected to be above the DI loop saturation current I_{c} such that photon detection events do not switch the hTron without a ramp current.

When the combined ramp current and the integrated current I_{di} reaches the hTron threshold, the hTron channel switches to high impedance and generates a voltage such that the gates of transistors M₂ and M₃, which form an inverter, are switched. The hTron channel switches a superconducting element from a superconducting state to normal state, and purges the integrated current I_{di}. Switching the inverter formed by transistors M₂ and M₃ reduces the voltage to transistor M₄, which in turn switches off the current flow to capacitor Cᵢₙₜ. The accumulated charge Qᵢₙₜ on capacitor Cᵢₙₜ provides a representation of integrated current I_{di} and the information on the state of the pixel just before measurement. However, charge Qᵢₙₜ is inversely proportion to integrated current I_{di}. If integrated current I_{di} is zero, then transistor M₄ will stay open for about the duration of the read operation, delivering the maximum charge Qᵢₙₜto capacitor Cᵢₙₜ. If integrated current I_{di} is about the saturation value, transistor M₄ will turn on briefly to deliver a smaller charge Qᵢₙₜ to capacitor Cᵢₙₜ.

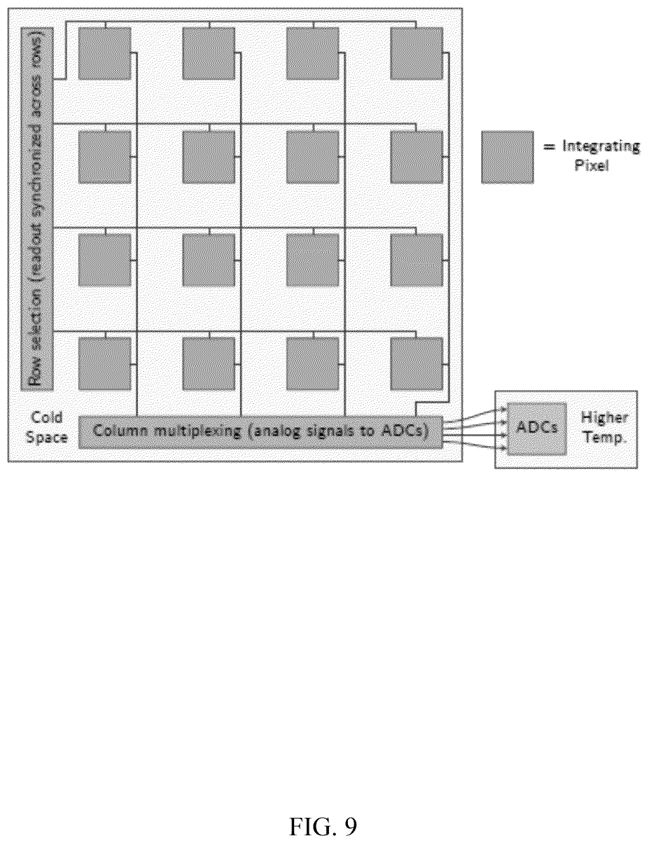

The accumulated charge Qᵢₙₜ on capacitor Cᵢₙₜ can be read by opening transistor M₅ with a read voltage and transferring the accumulated charge Qᵢₙₜ to a multiplexing circuit through a column bus. Transistor M₅ is positoned to provide an access line to capacitor Cᵢₙₜ for reading the accumulated charge Qᵢₙₜ on capacitor Cᵢₙₜ. FIG. 9 illustrates an exemplary readout architecture for a SPD pixel array in accordance with an embodiment of the present invention. Rows will be selected sequentially for readout with each row having a predetermined read time. In one embodiment of the present invention, each row will have up to about 100 ns for read time to enable a 100 us frame time at 10 kHz frame rate. Data will be sent down each column bus on this clock. The multiplexing circuit is configured to receive readout signals from selected rows of an array of SPD pixel sensors through each column bus of a set of column buses in parallel and transfer the readout signal data from each column bus to analog to digital converters (ADCs). The digitized signal from ADC is transferred to a processor for further analysis and processing.

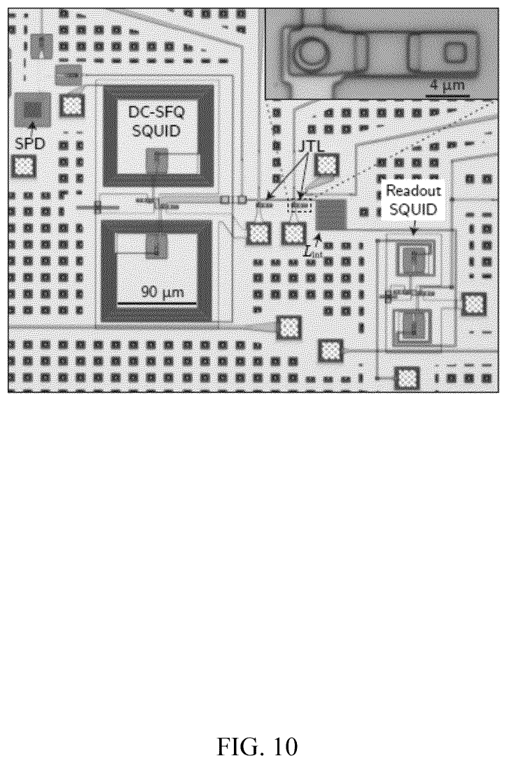

FIG. 10 illustrates a microscopic image of an exemplary fabricated SPD pixel in accordance with an embodiment of the present invention. The fabricated SPD pixel includes fifteen mask layers. Electron-beam lithography was used for fabricating the SPD, and all other patterning was accomplished with photolithography using a 365 nm i-line stepper. A 40 nm Nb wiring layer for contact to the SPDs was patterned using a liftoff process. Liftoff was used to avoid a vertical edge and provide a gradual, sloping contact for the thin film used for the SPDs. The SPDs were formed from a 4.1 nm thick MoSi film, which was sputtered after the Nb contact layer. The MoSi was patterned into a detector meander using electron-beam lithography to realize wire widths of about 200 nm. An interlayer dielectric insulates the SPD layer from a Nb ground plane above it. The JJ trilayer stack (Nb-aSi-Nb) is then deposited and patterned above the ground plane, with another SiO₂ insulator in between. PdAu resistors are patterned and deposited with liftoff to form the JJ shunt resistors. An additional low-resistance Au layer was used to make resistors with small values and long attainable leak time constants in the integrating loops used in power-meter mode. An additional top insulator sealed the structures. All layers were connected with Nb vias through the insulators. Measurements on the exemplary SPD pixel sensor, as shown in FIG. 10, were performed at 2.3K in a closed cycle Gifford-McMahon cryostat. The chip was flood illuminated by a fiber-coupled, 780 nm pulsed laser source. The laser pulse width was approximately 480 ps, while the SPD recovery time was around 37.5 ns. The maximum voltage (V_{SQ}) from the readout SQUID was on the order of 10 μV, and a room-temperature amplified with 60 dB voltage gain was used for measurements.

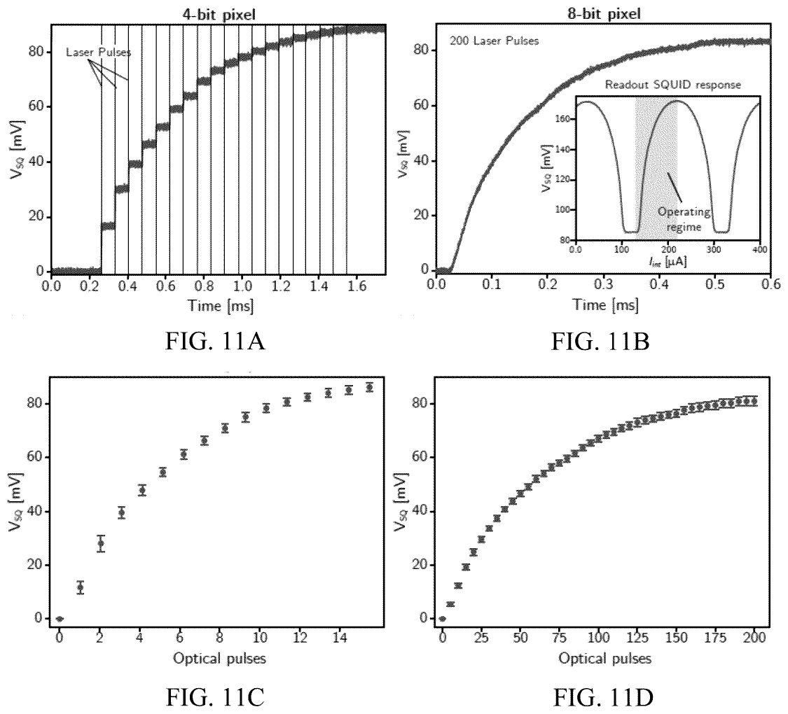

FIGS. 11A and 11B show the voltage across the DC-SFQ SQUID (shown in FIG. 10) as a function of time while optical pulses are directed at the SPD at a fixed rate. FIG. 11A shows the response to a train of 16 input optical pulses for a 4-bit pixel having an integration loop inductance of about 330 pH. FIG. 11B shows the response to a train of 256 input optical pulses for an 8-bit pixel having an integration loop inductance of about 5.3 nH. FIG. 11A shows discrete steps for each laser pulse as a fluxon enters the integration loop. The fluxon pulses are identical, but the measured response is nonlinear because it is convoluted with the response of the readout SQUID. The readout SQUID response is shown in FIG. 11B (inset). The response shown in FIG. 11B includes the same discrete steps but are not discernible as they are smaller than the noise, which in this case is due to line noise coupled from cryostat compressor to measurement electronics. The full readout scheme, described next, would eliminate both the non-linearity and the noise. FIGS. 11C and 11D show statistical analysis of the small and large storage capacity loops, respectively. The data points are the SQUID voltage averaged over 1000 independently measured traces. Each trace was taken after the number of photonic pulses indicated on the x-axis. The error bars give the standard deviation calculated from 1000 traces. After each trace was generated and recorded, the current in the integration loop was erased by driving current through a PdAu resistor, fabricated in closed vicinity to the inductor Lint in the DI loop. To reset the state of the DI loop, a 10 mA current was applied to the resistor, which heated the inductor, broke superconductivity, and purged the integrated current in the loop.

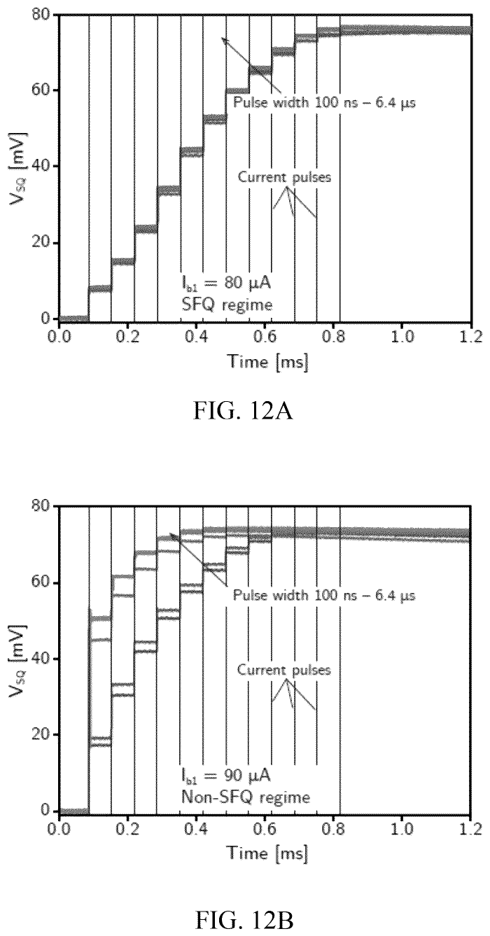

Current pulses, instead of optical pulses, that exceeded the switching current were directed to the SPD to ensure the photon counters are working in SPD-SFQ mode. This allowed changes to the width of the input pulses. An SPD-SFQ converter generates one SFQ pulse for each input pulse, regardless of the duration of the input pulse. FIG. 12A shows the device response for the current pulse width varying from 100 ns to 6.4 μs, in steps of a factor of two (geometrically spaced). No significant change in the output of the device is observed. The inductor in the integration loop can hold about 16 SFQ pulses before it saturates. Because the integration loop does not saturate at a lower number of pulses when driven with a larger pulse width, it can be concluded that the device is operating in the SPD-SFQ regime. In FIG. 12B, the bias to the SFQ SQUID is increased from 80 μA to 90 μA, which moved the circuit outside the SPD-SFQ regime. In this case, the integration loop saturates with fewer pulses as the pulse width is increased. Furthermore, the readout SQUID voltage step should be less than about 10 mV for a single SFQ pulse, considering the inductance of the integration loop, room temperature amplification, and operating point on the readout SQUID response curve. Accordingly, at about 80 μA SFQ-SQUID bias, the device was working in the desired SPD-SFQ mode, while by 90 μA SFQ-SQUID bias it was no longer generating one fluxon per photon detection event.

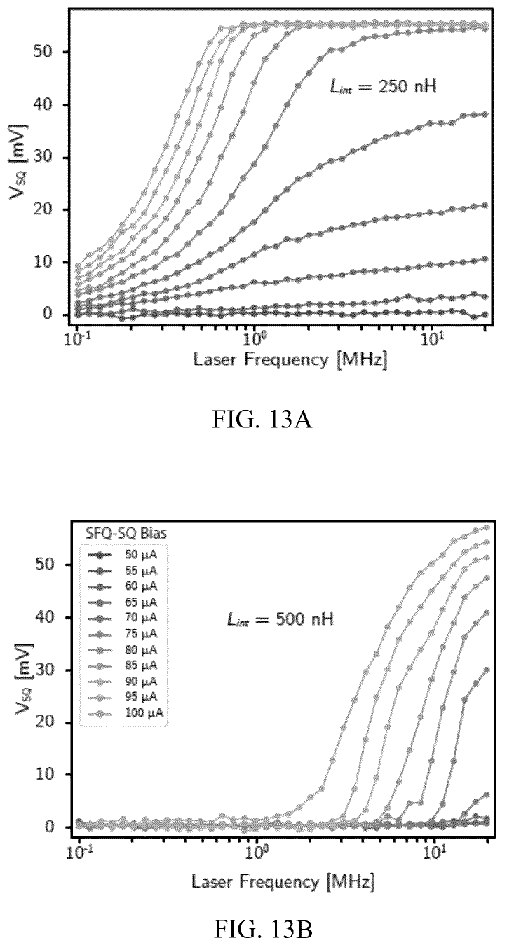

In addition to the digital SPD-SFQ operation described herein, measurements were obtained using similar circuits operated in analog power-meter mode. The circuit used for this mode was modified to include an initial transduction SQUID (also referred to as SPD-SFQ transduction circuit herein) having higher symmetric inductances. This symmetric design is employed to implement an analog transduction operation. The modified circuit also included a resistor in the integration loop to provide a leak rate. In the analog power meter mode, the initial transduction SQUID produces a stream of fluxons with each detection event. The number of fluxons generated with each detection event is determined by the bias current I_{b1}, which provides a control knob to adjust the response of the pixel based on the light level. The decay time in this exemplary circuit is about 6.25 μs, which is determined by the L/R decay time of the integration loop. The device reaches a steady state for sufficiently long pulse trains at a predetermined frequency, which can be further tuned with bias current I_{b1}. FIGS. 13A and 13B show the voltage on the readout SQUID as a function of the frequency of input photonic pulses. The different traces correspond to different values of bias current I_{b1}, and this dynamically variable control parameter can be used to adjust the response to keep the pixel in a dynamic range. The pixel can reach a different steady state value for predetermined values of bias current I_{b1} and input rate of photons, which can then be used to determine the incident light flux through a calibration procedure. FIGS. 13A and 13B show the measured SQUID voltage as a function of the incident pulse rate for values of the bias current I_{b1} from 50 μA to 100 μA, demonstrating tuning across several orders of magnitude in incident photon flux. These are the transfer functions that can be used to determine the rate of incident photons. FIG. 13A shows data for the device with an inductance of about 250 nH in the DI loop, and FIG. 13B shows data for the device with an inductance of about 500 nH in the DI loop. It can be observed that the dynamic range of the smaller capacity loop is better matched to the signal with this range of input signal rates and integration-loop leak rate.

The inventor has discovered that reading SPD pulses through Josephson electronics can reduce the effect of amplifier noise compared to stand-alone SPD readout. In the stand-alone SPD readout scheme, the SPD is connected to an amplifier through a bias tee. If there are high-frequency reflections from the amplifier, they will pass though the bias tee and affect the SPD. This amplifier noise will result in lowering the SPD operating range and limit the device operation to a smaller plateau. On the other hand, in the integrated SPD scheme in accordance with the present invention, the SPD is not connected to a bias tee. It is isolated from the amplifier though two superconductor SQUID transformers, leading to a more stable SPD bias current.

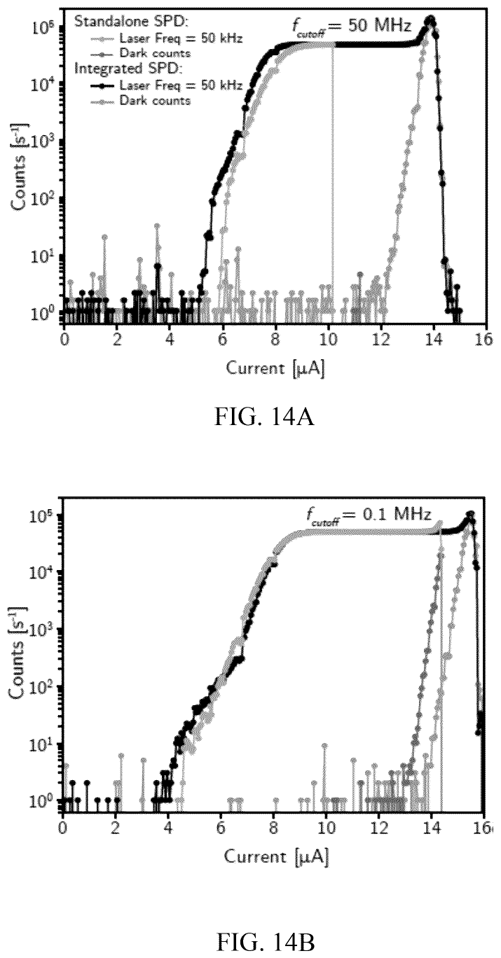

FIGS. 14A and 14A show the count rate versus SPD bias current for both a standalone and an integrated SPD that were fabricated on the same wafer, with the same geometry, located in close proximity on the chip. A power meter device with a leak in the integration loop was used for the integrated SPD. For sufficiently low laser frequency, the decay time in the DI loop is smaller than the separation of laser pulses, and the individual voltage pulses were discernable and could be counted using a commercial pulse counter. A laser frequency of 50 kHz was used for both standalone and integrated SPD. In FIG. 14A, a room temperature amplifier having a lower cutoff frequency of 50 MHz was used, and frequencies below 50 MHz were reflected from the amplifier. This lowered the operating range of the standalone SPD. The integrated SPD was not affected by the reflection, and resulted in an improvement in the width of the plateau region by a factor of three. FIG. 14B shows results observed from similar experiment with an amplifier having 0.1 MHZ lower cutoff frequency. Although the plateau region of the standalone SPD appears to match that of the integrated device, the integrated SPD still has a plateau region that is larger than the standalone SPD by about 15%.

Superconducting signal storage circuit in accordance with embodiments of the present invention have several advantages over previous signal storage circuits. Superconducting signal storage circuit in accordance with embodiments of the present invention include transduction circuits that integrate signals locally. This capability is realized by the monolithic integration of superconducting signal storage circuits with Josephson electronics. In these circuits, a superconducting signal storage circuit works in conjunction with JJ circuits to transduce electrical signals into current that can be stored indefinitely in a superconducting loop. In embodiments using SPD pixels, the pixels can operate in different modes: photons can be counted individually, with each detection event adding an identical amount of supercurrent to an integrating clement; or an active gain control option, in which the signal added per detection event can be dynamically adjusted to account for variable light conditions. Further, the pixels can either retain signal indefinitely to record all counts incurred over an integration period, or the pixels can record a fading signal of detection events within a decay time constant. Integration of superconducting signal storage circuit with Josephson electronics decouples detection events from the readout process. Low-noise readout is accomplished through a measurement duration that is not limited by the temporal extent of the current pulse. This measurement is accomplished with transistor circuits that transduce the integrated current signal to charge on a capacitor. The semiconductor readout circuit is a scalable large-format sensor arrays of superconducting single photon detectors compatible with CMOS array readout architectures. Through the integration with CMOS circuitry, this approach to readout of signal in superconducting storage elements allows reconfigurability of the array, enables the process of adding signal to the storage element to be independent from the readout of the signal, and facilitates scaling to very large systems with many storage elements.

Superconducting signal storage circuits in accordance with embodiments of the present invention can be adapted to a variety of configurations. It is thought that Superconducting signal storage circuits in accordance with various embodiments of the present invention and many of its attendant advantages will be understood from the foregoing description and it will be apparent that various changes may be made without departing from the spirit and scope of the invention or sacrificing all of its material advantages, the form hereinbefore described being merely a preferred or exemplary embodiment thereof.

Those familiar with the art will understand that embodiments of the invention may be employed, for various specific purposes, without departing from the essential substance thereof. The description of any one embodiment given above is intended to illustrate an example rather than to limit the invention. This above description is not intended to indicate that any one embodiment is necessarily preferred over any other one for all purposes, or to limit the scope of the invention by describing any such embodiment, which invention scope is intended to be determined by the claims, properly construed, including all subject matter encompassed by the doctrine of equivalents as properly applied to the claims.

What is claimed is:

1. A superconducting signal storage circuit comprising:
a transduction circuit for generating an integrated first current pulse in response to a plurality of electrical signals received from an input circuit;
a first transistor for applying a second current to interrogate the first current generated by the transduction circuit, wherein the second current is added to the first current to generate a third current;
a second transistor for generating a fourth current, wherein the fourth current is substantially equal to the first current from the transduction circuit;
a cryotron switching element comprising a cryotron gate and a cryotron channel, wherein the cryotron switching element is positioned to receive the third current through the cryotron gate and a fifth current through the cryotron channel, wherein the cryotron switching element switches the cryotron gate and the cryotron channel from a superconducting state to a normal metal state at a threshold value of the third current, wherein the fifth current through the switched cryotron channel in the normal metal state induces a first voltage;
a capacitor positioned to receive the fourth current from the second transistor and accumulate a charge equivalent to the received fourth current;
a semiconductor element comprising a third transistor and a fourth transistor for inducing a second voltage, wherein the first voltage induced by the switched cryotron channel switches off the third and the fourth transistors, wherein the switched off the third and the fourth transistors induce the second voltage, wherein the induced second voltage switches off the fourth current to the capacitor;
a fifth transistor coupled to the capacitor to provide an access line for reading the accumulated charge on the capacitor, wherein a third voltage opens the fifth transistor to transfer the accumulated charge on the capacitor to the access line as a readout signal; and
a column bus coupled to the fifth transistor to receive the readout signal.

2. The superconducting signal storage circuit of claim 1, further comprising:
a multiplexing element for multiplexing the readout signal received by the column bus; and
an analog-to-digital converter for converting the multiplexed readout signal to a digital signal.

3. The superconducting signal storage circuit of claim 1, wherein the cryotron switching element is a heater cryotron (hTron) switching element.

4. The superconducting signal storage circuit of claim 1, wherein the cryotron switching element is a nano cryotron (nTron) switching element.

5. The superconducting signal storage circuit of claim 1, wherein the cryotron switching element is a current-crowding cryotron (yTron) switching element.

6. The superconducting signal storage circuit of claim 1, wherein each of the first, the second, the third, the fourth and the fifth transistors is a metal oxide semiconductor field effect transistor.

7. The superconducting signal storage circuit claim 1, wherein the tranduction circuit comprises:
a direct current single-flux-quantum converter for converting each of the plurality of the electrical signals received from the input circuit to a single-flux-quantum;
a detector integration loop for inducing the integrated first current proportional to the single-flux-quantum converted for each of the plurality of the electrical signals received from the input circuit; and
a Josephson transmission line comprising a plurality of Josephson junctions for propagating the single-flux-quantum from the direct current single-flux-quantum converter to the detector integration loop.

8. A superconducting signal storage circuit comprising:
a direct current single-flux-quantum converter for converting each of a plurality of electrical signals received from an input circuit to a single-flux-quantum;
a detector integration loop for inducing an integrated first current proportional to the single-flux-quantum converted from the each of the plurality of the electrical signals received from the input circuit;
a Josephson transmission line comprising a plurality of Josephson junctions for propagating the single-flux-quantum from the direct current single-flux-quantum converter to the detector integration loop; and
a readout element for reading the induced integrated first current from the detector integration loop, wherein the readout element comprises:
a first transistor for applying a second current to the integrated first current from the detector integration loop circuit to generate a third current;
a second transistor for generating a fourth current, wherein the fourth current is substantially equal to the first current from the detector integration loop circuit;
a cryotron switching element comprising a cryotron gate and a cryotron channel, wherein the cryotron switching element is positioned to receive the third current through the cryotron gate and a fifth current through the cryotron channel, wherein the cryotron switching element switches the cryotron gate and the cryotron channel from a superconducting state to a normal metal state at a threshold value of the third current, wherein the fifth current through the switched cryotron channel in the normal metal state induces a first voltage;
a capacitor positioned to receive the fourth current from the second transistor and accumulate a charge equivalent to the received fourth current;
a semiconductor element comprising a third transistor and a fourth transistor for inducing a second voltage, wherein the first voltage induced by the cryotron channel switches off the third and the fourth transistors, wherein the switched off the third and the fourth transistors induce the second voltage, wherein the induced second voltage switches off the fourth current to the capacitor;
a fifth transistor coupled to the capacitor to provide an access line for reading the accumulated charge on the capacitor, wherein a third voltage opens the fifth transistor to transfer the accumulated charge on the capacitor to the access line as a readout signal; and
a column bus coupled to the fifth transistor to receive the readout signal.

9. The superconducting signal storage circuit of claim 8, further comprising:
a multiplexing element for multiplexing the readout signal received by the column bus; and
an analog-to-digital converter for converting the multiplexed readout signal to a digital signal.

10. The superconducting signal storage circuit of claim 8, wherein the cryotron switching element is a heater cryotron (hTron) switching element.

11. The superconducting signal storage circuit of claim 8, wherein the cryotron switching element is a nano cryotron (nTron) switching element.

12. The superconducting signal storage circuit of claim 8, wherein the cryotron switching element is a current-crowding cryotron (yTron) switching element.

13. The superconducting signal storage circuit of claim 8, wherein each of the first, the second, the third, the fourth and the fifth transistors is a metal oxide semiconductor field effect transistor.

14. A superconducting signal storage circuit comprising:
a first transistor for applying a first current to an integrated second current received from a transduction circuit, wherein the applying the first current to the integrated second current comprises adding the first current to the integrated second current to generate a third current;
a second transistor for generating a fourth current, wherein the fourth current is substantially equal to the integrated second current;
a cryotron switching element positioned to receive the third current through a cryotron gate and a fifth current through a cryotron channel, wherein the cryotron switching element switches the cryotron gate and the cryotron channel from a superconducting state to a normal metal state at a threshold value of the third current, wherein the fifth current through the switched cryotron channel in the normal metal state induces a first voltage;
a capacitor positioned to receive the fourth current from the second transistor and accumulate a charge equivalent to the received fourth current;
a semiconductor element comprising a third transistor and a fourth transistor for inducing a second voltage, wherein the first voltage induced by the switched cryotron channel switches off the third and the fourth transistors, wherein the switched off the third and the fourth transistors induce the second voltage, wherein the induced second voltage switches off the fourth current to the capacitor;
a fifth transistor coupled to the capacitor to provide an access line for reading the accumulated charge on the capacitor, wherein a third voltage opens the fifth transistor to transfer the accumulated charge on the capacitor to the access line as a readout signal; and
a column bus coupled to the fifth transistor to receive the readout signal.

15. The superconducting signal storage circuit claim 14, wherein the tranduction circuit comprises:
a direct current single-flux-quantum converter for converting each of a plurality of electrical signals received from an input circuit to a single-flux-quantum;
a detector integration loop for inducing the integrated first current proportional to the single-flux-quantum converted for each of the plurality of the electrical signals received from the input circuit; and
a Josephson transmission line comprising a plurality of Josephson junctions for propagating the single-flux-quantum from the direct current single-flux-quantum converter to the detector integration loop.

16. The superconducting signal storage circuit of claim 14, further comprising:
a multiplexing element for multiplexing the readout signal received by the column bus; and
an analog-to-digital converter for converting the multiplexed readout signal to a digital signal.

17. The superconducting signal storage circuit of claim 14, wherein the cryotron switching element is a heater cryotron (hTron) switching element.

18. The superconducting signal storage circuit of claim 14, wherein the cryotron switching element is a nano cryotron (nTron) switching element.

19. The superconducting signal storage circuit of claim 14, wherein the cryotron switching element is a current-crowding cryotron (yTron) switching element.

20. The superconducting signal storage circuit of claim 14, wherein each of the first, the second, the third, the fourth and the fifth transistors is a metal oxide semiconductor field effect transistor.
